(19) United States
(12) Patent Application Publication
(10) Pub. No.: US 2008/0305609 A1
(43) Pub. Date: Dec. 11, 2008

(54) METHOD FOR FORMING A SEAMLESS SHALLOW TRENCH ISOLATION

(76) Inventor: Hui-Shen Shih, Chang-Hua Hsien (TW)

Correspondence Address: NORTH AMERICA INTELLECTUAL PROPERTY CORPORATION, P.O. BOX 506, MERRIFIELD, VA, 22116, US

(21) Appl. No.: 11/759,215

(22) Filed: Jun. 6, 2007

(51) Int. Cl. H01L 21/762

(52) U.S. Cl. 438/424; 257/E21.268; 257/E21.324; 257/E21.349; 257/E21.546

(57) ABSTRACT

A method for fabricating a seamless shallow trench isolation includes providing a semiconductor substrate having at least a shallow trench that is filled by a dielectric layer with a seam, forming a dielectric layer filling the shallow trench with a seam, forming at least one healing layer on the dielectric layer, and performing a low-temperature steam annealing process to eliminate the seam.

### BACKGROUND OF THE INVENTION

1. Field of the Invention

The present invention relates to a method for forming a seamless shallow trench isolation (STI) and more particularly, to a method that improves efficiency and results in remedy for a seam formed in the STI.

2. Description of the Prior Art

As the critical dimension of semiconductor fabrication decreases, shallow trench isolations (STIs) used to provide electrical isolation between devices become increasingly important. Also, miniaturization of devices, and increased integration reduce width of the STI. In other words, aspect ratio (a ratio of height/depth of an object to its width) of the STI becomes larger and larger. Therefore, methods for filling in the narrow shallow trench effectively, and thus providing reliable electrical isolation, are a challenge in the field.

Please refer to FIG. 1, which is a sectional drawing of a conventional STI. As shown in FIG. 1, a conventional method for fabricating an STI starts with providing a substrate 10, and a hard mask layer 30 including a pad oxide layer 32 and a silicon nitride layer 34 formed thereon. The hard mask layer 30 is patterned, and then at least a shallow trench 20 is formed in the substrate 10 through the patterned hard mask layer 30. Next, a thermal oxidation process is performed to form a silicon oxide liner layer 22 on sidewalls and a bottom of the shallow trench 20. Subsequently, a chemical vapor deposition (CVD) process is performed to form a dielectric layer filling the shallow trench 20, and an etch back process or a chemical mechanic polishing (CMP) process is performed to remove the dielectric layer outside the shallow trench 20 to obtain a planar surface. However, since the aspect ratio of the STI is increasing, the conventional CVD methods no longer provide satisfactory step coverage when dealing with shallow trenches having such a large aspect ratio.

To overcome the difficulty mentioned above, many improved CVD methods are utilized, and one of which is an ozone-assisted sub-atmospheric pressure chemical vapor deposition (SACVD), which is found to have advantages over other CVD methods. SACVD is performed to form a dielectric 40, such as a silicon oxide layer, at a sub-atmospheric pressure of about 60 torrs, with ozone and tetra-ethyl-ortho-silicate (TEOS) serving as initial gases in a reaction occurring in a hydrogen/oxygen environment. The silicon oxide layer 40 formed by the SACVD process has a superior gap filling ability that is particularly desirable for shallow trenches with large aspect ratio. Then, a high-temperature annealing process is performed for densifying the silicon oxide layer at a temperature of about 1000° C. in a nitrogen environment.

However, the SACVD process still has several drawbacks in practical use. First, after the high-temperature annealing process, the silicon oxide layer 40 formed is apt to shrink. For example, a shrinkage of about 7% has been observed after annealed at 1050° C. for 30 minutes. Further, quality of the silicon oxide layer 40 formed by the SACVD process is relatively inferior, e.g. resistance to wet etchants is not high enough. Another noteworthy drawback encountered when employing SACVD is specifically depicted in FIG. 1. Since the SACVD film deposition is conformal and uniform along sidewalls of the shallow trench 20, a seam defect 42 is left near the center line of the shallow trench 20 when the shallow trench 20 is filled up. Moreover, the SACVD film is grown in non-uniformity, therefore a void with a seam atop may be formed. The seam defect 50 is concerning, because it cannot be removed merely by the high-temperature annealing process mentioned above, and because it is subject to corrosion or attacks by the wet etchant used in subsequent wet cleaning procedures. Therefore a steam annealing process is utilized to eliminate the seam defect 42 before performing the high-temperature annealing process. The steam annealing process is performed at a low temperature of about 700° C. in a hydrogen/oxygen environment for a period longer than 30 minutes. However, the low-temperature steam annealing process is time-consuming, and its result in remedy for the seam still needs improvement.

### SUMMARY OF THE INVENTION

Therefore the present invention provides a method for fabricating a seamless shallow trench isolation to eliminate the seam defect in the shallow trench induced by the SACVD process.

According to the present invention, a method for fabricating a seamless shallow trench isolation (STI) is provided. The method includes providing a semiconductor substrate having at least a shallow trench that is filled by a dielectric layer with a seam, forming at least one healing layer on the dielectric layer, and performing a low-temperature steam annealing process to eliminate the seam.

According to the method for fabricating seamless shallow trench isolation (STI) provided by the present invention, a healing layer providing dangling bonds is formed. The dangling bonds serve as recombination centers. Therefore both the efficiency and the result of the seam elimination effected by the low-temperature steam annealing process are improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a conventional STI.

FIGS. 2-6 are schematic drawings illustrating a preferred embodiment provided by the present invention.

FIG. 7 is a flowchart of a method for fabricating seamless STI.

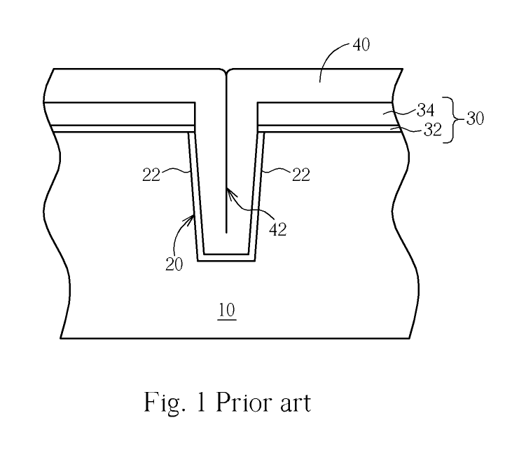

### DETAILED DESCRIPTION

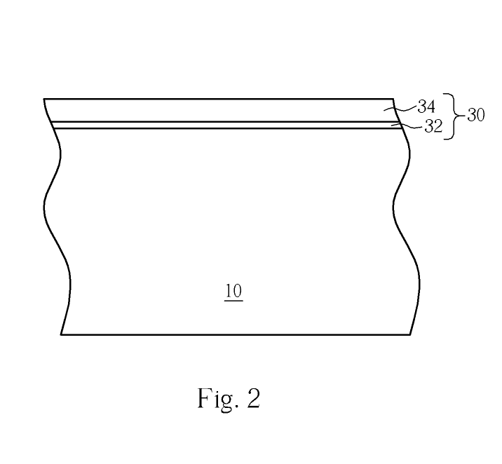

Please refer to FIGS. 2-6, which are schematic drawings illustrating a preferred embodiment of the present invention for eliminating a seam formed in an STI by an SACVD process. As shown in FIG. 2, a semiconductor substrate 10 such as a silicon substrate is provided. The semiconductor substrate 10 includes a pad oxide layer 32 with a thickness of about 30-200 angstroms and a silicon nitride layer 34 with a thickness of 500-2000 angstroms subsequently formed thereon. The pad oxide layer 32 and the silicon nitride layer 34 are used as a hard mask layer 30.

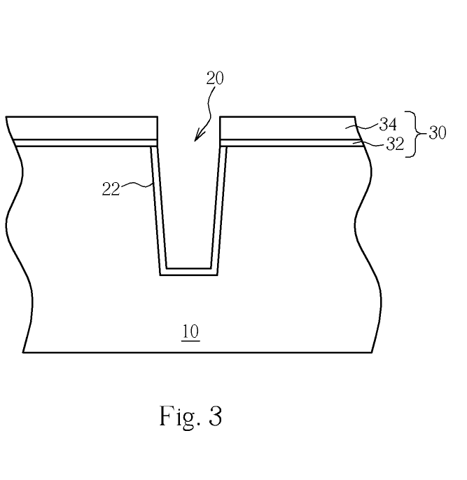

Please refer to FIG. 3. Next, conventional lithographic and etching processes are performed with a photoresist (not shown) to pattern the hard mask layer 30 and to form at least an opening in the hard mask layer 30. After removing the photoresist, the semiconductor substrate 10 is etched through the opening, and a shallow trench 20 is formed accordingly. After forming the shallow trench 20, a thermal oxidation process is performed to form a silicon oxide liner layer 22 on sidewalls and a bottom of the shallow trench 20.

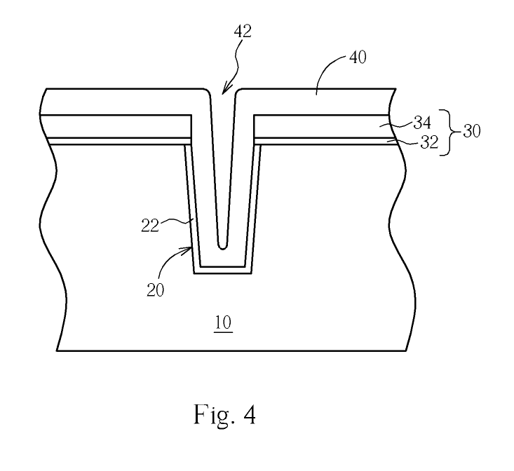

Please refer to FIG. 4. Then, an SACVD process is performed at a sub-atmospheric pressure of about 60 torrs, with ozone and tetra-ethyl-ortho-silicate (TEOS) serving as initial gases in a reaction. A dielectric layer 40, such as a silicon oxide layer, filling the shallow trench 20 is formed with a uniform thickness. As mentioned above, the silicon oxide layer 40 formed by the SACVD process is conformal and uniform along the sidewalls and the bottom of the shallow trench 20, thus a seam 42 is left near the center line of the shallow trench 20 when it is filled up. Even a void with a seam stop may formed due to the non-uniformity of the dielectric layer 40. The seam 42 is subject to corrosion or attacks by a wet etchant used in subsequent wet cleaning procedures.

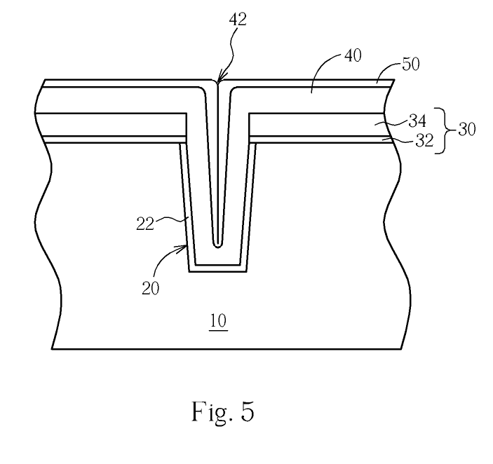

Please refer to FIG. 5. Therefore, at least one healing layer 50 formed on the silicon oxide layer 40 is provided by the preferred embodiment of the present invention. The healing layer 50 can be a Si-rich layer having a refractive index greater than 1.6 or having a silicon content greater than 30% wt. For example, the healing layer 50 can be silane, trimethylsilane, tetramethylsilane, dimethylsilane, diethylsilane, tetra-ethyl-ortho-silicate (TEOS), dichlorosilane (SiCl₂H₂), or tetra-methyl cyclo tetra-siloxane (TMCTS). In addition, the healing layer 50 can be a pure silicon layer formed by treating a surface of the dielectric layer 40 with silane. A thickness of the healing layer 50 is about 0-100 angstroms and is adjustable depending on a thickness of the dielectric layer 40 or the aspect ratio of the shallow trench 20. For instance, when the healing layer 50 is a Si-rich layer and the thickness of the dielectric layer 40 is about 5900 angstroms, the thickness of the healing layer 50 is about 100 angstroms.

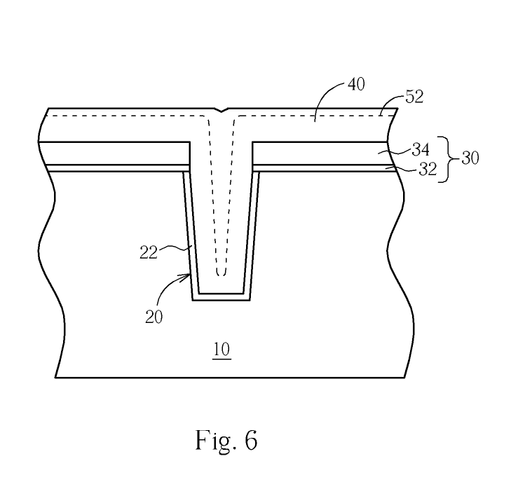

Please refer to FIGS. 5-6. After forming the healing layer 50 on the dielectric layer 40, a low-temperature steam annealing process is performed to eliminate the seam 42, even the void with a seam atop, in a hydrogen/oxygen environment. Particularly, the low-temperature steam annealing process is performed at a hydrogen flowrate of 5-20 L/min and a oxygen flowrate of 5-20 L/min and at a temperature of 500-800° C.

Please note that because the healing layer 50 is a Si-rich layer, the silicon atoms on the surface of the Si-rich layer have dangling bonds, which provide electrons and electron holes that serve as recombination centers. Therefore, silicon oxide can be formed in the healing layer 50 in the low-temperature steam annealing process assisted and improved by the recombination centers. Thus, the efficiency and result of the seam elimination are simultaneously improved. In addition, when the healing layer 50 is a pure silicon layer formed by treating the dielectric layer 40 with silane, the dangling bonds of the silicon atoms also form on the surface of the healing layer 50. In the same concept, the dangling bonds provide electrons and electron holes that serve as recombination centers. Therefore, silicon oxide can be formed in the low-temperature steam annealing process with improved efficiency and result. In other words, the healing layer 50 shortens the period required to complete the low-temperature steam annealing process to less than 30 minutes, and the result of seam elimination improves simultaneously.

Furthermore, according to the preferred embodiment of the present invention, a UV treatment can be performed before performing the low-temperature steam annealing process. The UV treatment makes the healing layer 50 shrink slightly, thus slightly widening the seam 42, such that hydrogen/oxygen may be introduced into the seam 42 unobstructed, making the reaction with the healing layer 50 more complete. In addition, energy provided by the UV light causes more dangling bonds to form in the surface of the healing layer 50. As mentioned above, the dangling bonds serve as recombination centers in the low-temperature steam annealing process, therefore the efficiency and the result of the seam elimination are further improved.

After the low-temperature steam annealing process, a high-temperature annealing process is performed at a temperature of 900-1100° C. for densifying the dielectric layer 40. The low-temperature steam annealing process and the high-temperature annealing process can be performed in-situ or ex-situ. And, a CMP process is performed after the high-temperature annealing process to complete the STI formation. Since the process is well known to those skilled in the art, further details are omitted in the interest of brevity.

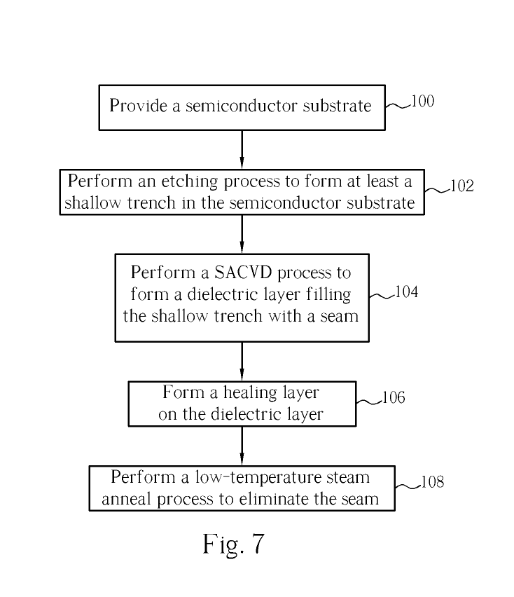

Please refer to FIG. 7, which is a flowchart of the method for fabricating the seamless STI provided by the present invention. As shown in FIG. 7, the steps of the method provided by the present invention are summarized as follows:

Step 100: Provide a semiconductor substrate.

Step 102: Perform an etching process to form at least a shallow trench in the semiconductor substrate.

Step 104: Perform an SACVD process to form a dielectric layer filling the shallow trench with a seam, even a void with a seam atop.

Step: 106: Form a healing layer on the dielectric layer.

Step 108: Perform a low-temperature steam annealing process to eliminate the seam.

Needless to say, step 106 and step 108 can be performed repeatedly depending on a size of the seam or the result of the remedy for the seam. Additionally, as mentioned above, after the step 108, which means after performing the low-temperature steam annealing process, a high-temperature annealing process can be performed for densifying the dielectric layer. Of course steps of forming a healing layer on the dielectric layer, performing a low-temperature steam annealing process, and performing a high-temperature annealing process can be performed repeatedly depending on a size of the seam or the result of the remedy for the seam.

As mentioned above, the method for fabricating seamless STI provided by the present invention further improves remedy for seam by forming a healing layer. The provided healing layer provides dangling bonds that serve as recombination centers, therefore both the efficiency and the result of the low-temperature steam annealing process are improved.

Those skilled in the art will readily observe that numerous modifications and alterations of the device and method may be made while retaining the teachings of the invention.

What is claimed is:

1. A method for fabricating a seamless shallow trench isolation (STI) comprising steps of:
providing a semiconductor substrate with a shallow trench being filled by a dielectric layer with a seam;
forming at least one healing layer on the silicon oxide layer; and
performing a low-temperature steam annealing process to eliminate the seam.

2. The method of claim 1, wherein the dielectric layer is formed by a sub-atmospheric pressure chemical vapor deposition (SACVD) process.

3. The method of claim 2, wherein the SACVD process is performed with ozone and tetra-ethyl-ortho-silicate (TEOS) as initial gases in a reaction.

4. The method of claim 1 further comprising a step of performing a UV treatment before the low-temperature steam annealing process.

5. The method of claim 1, wherein the healing layer comprises a Si-rich layer.

6. The method of claim 5, wherein the Si-rich layer has a refractive index greater than 1.6.

7. The method of claim 5, wherein the Si-rich layer is formed by at least one reaction gas selected from the group consisting of: silane, trimethylsilane, tetramethylsilane, dimethylsilane, diethylsilane, tetra-ethyl-ortho-silicate (TEOS), dichlorosilane (SiCl₂H₂), or tetra-methyl cyclo tetra-siloxane (TMCTS).

8. The method of claim 1, wherein the healing layer is formed by treating a surface of the silicon oxide layer with a silane.

9. The method of claim 8, wherein the healing layer comprises a pure silicon layer.

10. The method of claim 1, wherein the healing layer has a thickness of 0-100 angstroms.

11. The method of claim 1, wherein the low-temperature steam annealing process is performed in a hydrogen/oxygen environment.

12. The method of claim 11, wherein the low-temperature steam annealing process is performed with a hydrogen flowrate of 5-20 L/min and an oxygen flowrate of 5-20 L/min.

13. The method of claim 1, wherein the low-temperature steam annealing process is performed at a temperature of 500-800° C.

14. The method of claim 1 further comprising a step of performing a high-temperature annealing process to densify the silicon oxide layer after the low-temperature steam annealing process.

15. The method of claim 14, wherein the high-temperature annealing process is performed in a nitrogen environment.

16. The method of claim 14, wherein the high-temperature annealing process is performed at a temperature of 900-1100° C.

17. The method of claim 1, wherein steps of forming a healing layer on the dielectric layer and performing a low-temperature steam annealing process are performed repeatedly.

18. The method of claim 14, wherein steps of forming a healing layer on the dielectric layer, performing a low-temperature steam annealing process, and performing a high-temperature annealing process are performed repeatedly.
